(19) United States
(12) Patent Application Publication
(10) Pub. No.: US 2010/0001416 A1
(43) Pub. Date: Jan. 7, 2010

(54) WAFER LASER-MARKING METHOD AND DIE FABRICATED USING THE SAME

(76) Inventors: Yu-Pin Tsai, Kaohsiung City (TW); Cheng-Yi Huang, Hunei Township (TW); Yao-Hui Hu, Dashe Township (TW)

Correspondence Address: Muncy, Geissler, Olds & Lowe, PLLC, P.O. BOX 1364, FAIRFAX, VA, 22038-1364, US

(21) Appl. No.: 12/482,131

(22) Filed: Jun. 10, 2009

(30) Foreign Application Priority Data
Jul. 3, 2008 (TW) 97125143

(51) Int. Cl. H01L 23/544; H01L 21/304

(52) U.S. Cl. 257/797; 438/463; 257/E21.237; 257/E23.179

(57) ABSTRACT

A wafer laser-marking method is provided. First, a wafer having a first surface (an active surface) and a second surface (a back surface) opposite to each other is provided. Next, the wafer is thinned. Then, the thinned wafer is fixed on a tape such that the second surface of the wafer is attached to the tape. Finally, the laser marking step is performed, such that a laser light penetrates the tape and marks a pattern on the second surface of the wafer. There are glue residuals remained in the laser-marking pattern of the die manufactured according to the laser-marking method of the invention, and the components of the glue residuals at least include elements of silicon, carbon and oxygen.

This application claims the benefit of Taiwan application Serial No. 97125143, filed Jul. 3, 2008, the subject matter of which is incorporated herein by reference.

### BACKGROUND OF THE INVENTION

1. Field of the Invention

The invention relates in general to a wafer laser-marking method and a die manufactured using the same, and more particularly to a laser-marking method capable of precisely marking a desired pattern and a die manufactured using the same.

2. Description of the Related Art

Along with the rapid advance in technology, many electronic products featured by high speed, light weight, slimness and compactness are provided one by one. The main function of the packaging industry is to support the development of electronic products and assure that the speed of semiconductor packages keeps improving and the semiconductor packages function properly. Thus, the electronic products using the semiconductor packages can meet the market requirements of lightweight, slimness and compactness. In order to meet the users' needs, the way of packaging semiconductor packages also keeps being renewed so that the packages become further miniaturized.

Of the many factors that affect the development of the super-thinned package, the thickness of the chip is very crucial. The smaller the chip is, the easier it is to integrate many chips having different functions into one single small-sized package. The step of thinning the wafer is an indispensible step in the making of a small-sized chip. However, the thinner the wafer is, the easier the warpage will occur and affect subsequent process. For example, the laser light cannot precisely mark a pattern on the back surface of the wafer.

FIG. 1A˜FIG. 1D schematically illustrate a conventional wafer laser-marking method. Firstly, a wafer 10 having a first surface (an active surface) 101 and a second surface (a wafer back surface) 103 is provided, wherein a plurality of bumps 12 are disposed on the first surface 101. Typically, the first surface 101 is the active surface (the circuit surface) of the wafer 10, and the second surface 103 is the back surface (the non-circuit surface) of the wafer 10. Next, an adhesive layer 14 is disposed on the first surface 101 of the wafer 10 as indicated in FIG. 1A. The adhesive layer 14 can be any back grinding (BG) tape applicable to the thinned wafer 10. Then, the grinding step is performeded to thin the wafer 10 by grinding the second surface 103 of the wafer 10 as indicated in FIG. 1B.

After that, the periphery of the wafer 10 is fixed by a frame 16, then the wafer 10 and the frame 16 are positioned on a supporting structure (not illustrated), and a laser light is radiated on the second surface 103 of the wafer 10 to carve a desired laser marking (pattern), as indicated in FIG. 1C. The generated laser markings could be divided as large marks and white marks. Normally, a depth of large mark is approximately 0.1 μm, and a depth of white mark approximately ranges between 2 μm to 4 μm. Finally, the wafer 10 is singulated to form a plurality of dies 18.

However, as both the frame 16 and the supporting structure are both made of hard materials, warpage might easily occur to the thin wafer due to the gravity. That is, the center of thinned wafer 10 sinks and becomes lower than the two sides. It is very difficult for the laser light to precisely focus on the back surface of the wafer whose periphery has severe problem of warpage. The allowable tolerance of focusing point of the laser light (variation from a standard) is usually about 1 mm. Referring to FIG. 2, a wafer warpage and laser lights are schematically shown. As indicated in FIG. 2, the laser lights L1, L2, L3, L4 can be radiated on the back surface of the wafer to mark a pattern, wherein the laser light L1 corresponds to the center of the wafer. However, for the areas having server warpage (for example, the periphery of the wafer), the focal point of the laser light is not able to reach the back surface of the wafer. Take the laser light Ln for example, there is a distance between the focal point a of the laser light Ln and the back surface of the wafer, the laser light therefore cannot be radiated on the back surface of the wafer to mark a pattern precisely. Thus, the marking on the wafer has defects, not only reducing product yield rate but also increasing manufacturing cost.

### SUMMARY OF THE INVENTION

The invention is directed to a wafer laser-marking method capable of avoiding wafer warpage. Therefore, the laser light can precisely mark a desired pattern on the back surface of the wafer so as to increase the product yield.

According to the first aspect of the present invention, a wafer laser-marking method is provided. Firstly, a wafer having a first surface and a second surface opposite to each other is provided, wherein the first surface has a plurality of bumps. Next, the wafer is thinned. Then, the thinned wafer is fixed on a tape such that the second surface of the wafer is attached to the tape. Finally, the laser marking step is performed, such that a laser light penetrates the tape and marks a pattern on the second surface of the wafer.

According to the second aspect of the present invention, a silicon die including a first surface and a second surface is provided. The first surface has a plurality of bumps. The second surface is opposite to the first surface. There is an indented laser mark disposed on the second surface, wherein the indented laser mark has a glue residual whose components at least includes elements of silicon, carbon and oxygen.

The invention will become apparent from the following detailed description of the preferred but non-limiting embodiments. The following description is made with reference to the accompanying drawings.

### BRIEF DESCRIPTION OF THE DRAWINGS

FIG. 1A˜FIG. 1D (Prior Art) schematically illustrate a conventional wafer laser-marking method;

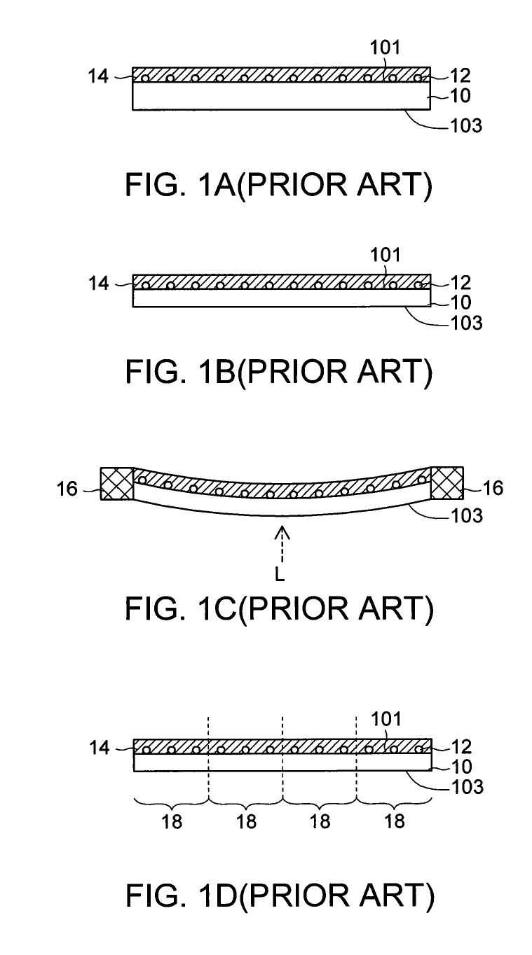

FIG. 2 (Prior Art) schematically shows a wafer warpage and laser lights; and

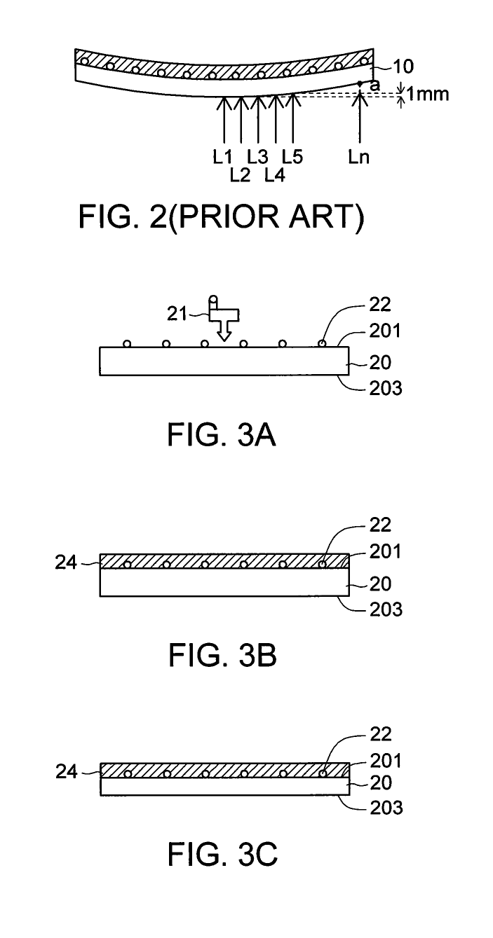

FIG. 3A˜FIG. 3G schematically illustrate a wafer laser-marking method according to a preferred embodiment of the invention.

### DETAILED DESCRIPTION OF THE INVENTION

The invention provides a wafer laser-marking method capable of avoiding wafer warpage, such that the laser light can precisely mark a desired pattern on the back surface of the wafer so as to increase product yield rate. Besides, there are glue residuals remained in the laser-marking pattern of the die manufactured according to the laser-marking method of the invention, and the components of the glue residuals at least include elements of silicon, carbon and oxygen.

A preferred embodiment accompanied with drawings disclosed below to elaborate a wafer manufacturing process of the invention. However, the disclosed embodiment and the wafer manufacturing process illustrated in the drawings are for exemplification purpose not for limiting the scope of protection of the invention. Thus, the specification and the drawings are to be regard as an illustrative sense rather than a restrictive sense. Moreover, the drawings used for illustrating the embodiments and applications of the present invention only show the major characteristic parts in order to avoid obscuring the present invention, and the secondary elements are omitted in the preferred embodiment to highlight the technical features of the invention.

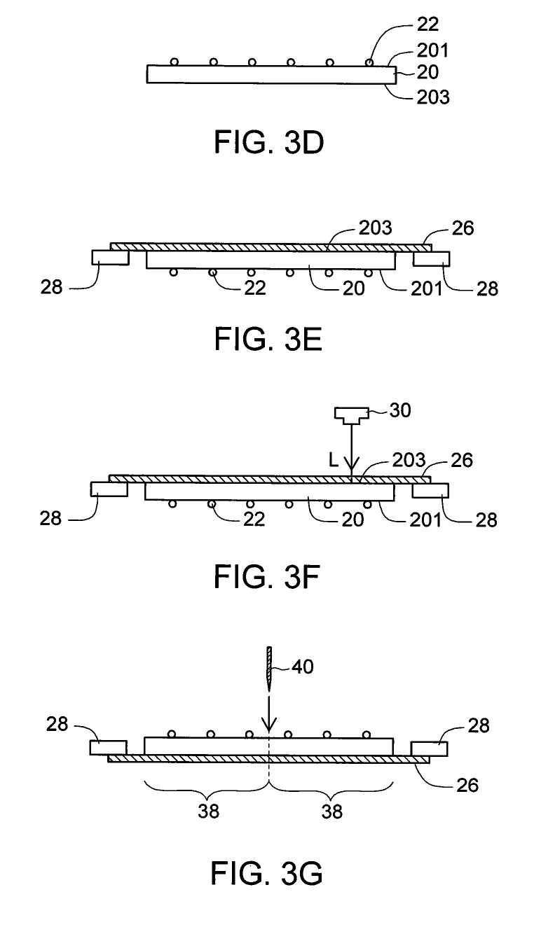

FIG. 3A˜FIG. 3G schematically illustrate a wafer laser-marking method according to a preferred embodiment of the invention. Firstly, a wafer 20 having a first surface (such as an active surface) 201 and a second surface (such as a wafer back surface) 203 is provided, wherein a plurality of bumps 22 are formed on the first surface 201. A plurality of solder balls could be formed on the first surface 201 as the bumps 22. An inspection device 21 such as a microscope is used for inspecting whether the wafer 20 or the implanted ball has any defects, as indicated in FIG. 3A. In the present embodiment, the first surface 201 is an active surface (a circuit surface) of the wafer 20, and the second surface 203 is a back surface (a non-circuit surface of the wafer 20).

Next, as indicated in FIG. 3B, an adhesive layer 24 is disposed on the first surface 201 of the wafer 20. The shape of the adhesive layer 24 is similar to that of the wafer 20 but the size of the adhesive layer 24 is slightly larger than that of the wafer 20. The adhesive layer 24 can be made of any back grinding (BG) tape applicable to the thinned wafer 20. In practical application, a round grinding frame (not illustrated) is used to flatly unfold the periphery of the adhesive layer 24, and then the adhesive layer 24 is attached to the first surface 201 of the wafer 20.

Then, the grinding step is performed on for thinning the wafer 20 by grinding the second surface 203 of the wafer 20, as indicated in FIG. 3C. The wafer can be thinned by way of mechanical grinding, chemical-mechanical polishing grinding, wet etching, atmospheric downstream plasma (ADP) or dry chemical etching (DCE). The invention does not have further limitations regarding the ways of thinning the wafer 20.

After the wafer 20 is thinned, the adhesive layer 24 is removed, as indicated in FIG. 3D. The way of removing the adhesive layer 24 is determined according to the characteristics of the adhesive layer. For example, the adhesive layer 24 may lose its adherence when heated at a high temperature or radiated by an ultra-velvet light.

Then, a tape 26 is attached on the second surface 203 of the thinned wafer 20 to fix the wafer 20, as indicated in FIG. 3E. In practical application, a frame 28 is provided, and the peripheral of the tape 26 is flatly unfolded on the frame 28 to form a flat surface. Next, the tape 26 is attached on the second surface 203 of the wafer 20. Due to the expansion of the tape 26, the surface of the wafer 20 attached on the tape 26 will remain flat and will be free of warpage.

In the present embodiment of the invention, the frame 28 is preferably a frame applicable to a laser apparatus (not illustrated) and a wafer cutting apparatus (not illustrated). The tape 26 is preferably a dicing tape applicable to the wafer cutting apparatus.

Afterwards, the frame 28 on which the wafer 20 has been fixed is moved to the laser apparatus, and a laser light L is emitted to the second surface 203 of the wafer 20 by a laser-exciting apparatus 30 (disposed at one side of the second surface 203 of the wafer 20) to perform the laser marking step, as indicated in FIG. 3F. In practical application, an image device such as a CCD (not illustrated) can be disposed beside the first surface 201 of the wafer 20, and the laser light L can be moved co-axially with the image device to complete the step of laser marking a pattern on the wafer 20. During the laser-marking step, the wafer 20 remains a flat surface and is free of warpage, so that the laser light L is capable of precisely focusing and marking the desired pattern on the back surface of the wafer.

During the conventional wafer manufacturing process, the laser light directly marks a pattern on the back surface of the wafer. According to the laser-marking step of the present embodiment of the invention, the laser light L penetrates the tape 26 to mark a pattern on the second surface 203 of the wafer 20, as indicated in FIG. 3E. Thus, there are glues remained in the laser-marking pattern of the die, and the components of the glue residuals at least include elements of silicon, carbon and oxygen after analysis. As for the generated laser mark, the indented depth ranges between about 0.1 μm to 4 μm.

After the laser marking step, the frame 28 on which the wafer 20 has been fixed is moved to a wafer cutting apparatus (not illustrated), and the first surface 201 of the wafer 20 is cut by a diamond cutter 40 or other cutting tools as indicated in FIG. 3G to divide the wafer 20 into a plurality of dies 38 attached on the tape 26.

To assure the quality of the diee, after the cutting, the wafer 20 is removed from the frame 28 and then sent to an inspecting machine such as a micro-scope to manually check whether the surfaces or the peripheries of the separated dies have scraps or chipping problems.

Finally, the dies are separated and selected. The qualified dies are picked up and placed on the tray one by one and then sent to the packaging factory for packaging.

Compared with the conventional laser-marking method, the laser-marking method of the invention first of all fixes the thinned wafer and makes the wafer flat and free of warpage, such that the laser light is capable of precisely marking a pattern on the back surface of the wafer and increasing product yield rate. Furthermore, in the present embodiment of the invention, the dicing tape applicable to the wafer cutting apparatus is used to fix the tape 26 of the thinned wafer 20 as indicated in FIG. 3E, so the subsequent process of cutting the wafer can be performed directly, further effectively simplifying the manufacturing process.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A wafer laser-marking method, comprising:
providing a wafer having a first surface and a second surface opposite to each other, and the first surface having a plurality of bumps;
thinning the wafer;
fixing the thinned wafer on a tape such that the second surface of the wafer is attached to the tape; and
performing a laser marking step such that a laser light penetrates the tape and marks a pattern on the second surface of the wafer.

2. The method according to claim 1, further comprises attaching an adhesive layer on the first surface of the wafer before thinning the wafer.

3. The method according to claim 2, wherein after thinning the wafer, the method further comprises the step of removing the adhesive layer.

4. The method according to claim 1, wherein the step of thinning the wafer is achieved by grinding the second surface of the wafer.

5. The method according to claim 1, wherein the step of fixing the thinned wafer further comprises:
providing a frame on which the tape is disposed; and
attaching the second surface of the wafer on the tape to fix the thinned wafer.

6. The method according to claim 5, wherein the periphery of the tape is flatly unfolded on the frame to form a flat surface attached to the second surface of the wafer.

7. The method according to claim 5, wherein the frame is applicable to a laser apparatus and a wafer cutting apparatus.

8. The method according to claim 5, wherein the frame is a circular frame, and the tape is a round tape.

9. The method according to claim 1, wherein the tape is a dicing tape which is applicable to a wafer cutting apparatus.

10. The method according to claim 1, wherein the laser marking step further comprises:
providing a laser-exciting apparatus at one side of the second surface of the wafer, such that the laser light penetrates the tape and marks a pattern on the second surface of the wafer.

11. The method according to claim 1, wherein after the laser marking step, the method further comprises cutting the wafer to form a plurality of separate dies attached on the tape.

12. The method according to claim 11, wherein the first surface of the wafer is cut by a cutting tool.

13. A silicon die, comprising:
a first surface having a plurality of bumps; and
a second surface opposite to the first surface, and the second surface having an indented laser mark, and the indented laser mark has a glue residual whose components at least comprise elements of silicon, carbon and oxygen.

14. The silicon die according to claim 13, wherein the generated laser mark has an indent whose depth ranges between about 0.1 μm to 4 μm.
